(19) United States
(12) Patent Application Publication
(10) Pub. No.: US 2026/0013334 A1
(43) Pub. Date: Jan. 8, 2026

(54) DISPLAY DEVICE

(71) Applicant: Japan Display Inc., Tokyo (JP)

(72) Inventor: Hiroshi TABATAKE, Tokyo (JP)

(73) Assignee: Japan Display Inc., Tokyo (JP)

(21) Appl. No.: 19/257,506

(22) Filed: Jul. 2, 2025

(30) Foreign Application Priority Data
Jul. 5, 2024 (JP) 2024-108944

(51) Int. Cl. H10K 59/122; H10K 59/80

(52) U.S. Cl. CPC H10K 59/122; H10K 59/80515

(57) ABSTRACT

According to one embodiment, a display device includes an organic insulating layer, a first lower electrode and a second lower electrode that are provided above the organic insulating layer and spaced apart from each other in a first direction, an inorganic insulating layer provided between the organic insulating layer and the first lower electrode and the second lower electrode, a rib layer, and a partition provided on the rib layer. The inorganic insulating layer has a first slit extending in a second direction intersecting the first direction. The partition has a second slit extending in the second direction and overlapping the first slit in plan view. The first slit and the second slit are located between the first lower electrode and the second lower electrode.

### CROSS-REFERENCE TO RELATED APPLICATION

This application is based upon and claims the benefit of priority from Japanese Patent Application No. 2024-108944, filed Jul. 5, 2024, the entire contents of which are incorporated herein by reference.

### FIELD

Embodiments described herein relate generally to a display device.

### BACKGROUND

Recently, display devices with organic light-emitting diodes (OLEDs) applied thereto as display elements have been put into practical use. In this type of display devices, a technique for suppressing degradation in display quality is requested.

### BRIEF DESCRIPTION OF THE DRAWINGS

FIG. 1 is a view showing a configuration example of a display device according to an embodiment.

FIG. 2 is a schematic plan view showing an example of the layout of subpixels.

FIG. 3 is a schematic plan view showing the subpixels shown in FIG. 2 in an enlarged manner.

FIG. 4 is a schematic cross-sectional view of the display device along the III-III line of FIG. 3.

FIG. 5 is a schematic plan view showing the vicinity of each of the contact holes shown in FIG. 3 in an enlarged manner.

FIG. 6 is a schematic cross-sectional view of the display device along the VI-VI line of FIG. 5.

FIG. 7 is a schematic plan view showing the vicinity of each of the contact holes shown in FIG. 3 in an enlarged manner.

FIG. 8 is a schematic cross-sectional view of the display device along the VIII-VIII line of FIG. 7.

FIG. 9 is a schematic plan view showing some elements of the display device.

FIG. 10 is a plan view showing an example of relationships among slits of partitions and slits of inorganic insulating layers.

FIG. 11 is a schematic cross-sectional view of the display device along the XI-XI line of FIG. 10.

FIG. 12 is a diagram for explaining an effect of the slits of the partitions.

FIG. 13 is a diagram for explaining an effect of the slits of the partitions.

FIG. 14 is a cross-sectional view of another example of the display device DSP shown in FIG. 11.

FIG. 15 is a cross-sectional view of still another example of the display device DSP shown in FIG. 11.

FIG. 16 is a cross-sectional view of still another example of the display device DSP shown in FIG. 11.

FIG. 17 is a cross-sectional view of still another example of the display device DSP shown in FIG. 11.

### DETAILED DESCRIPTION

In general, according to one embodiment, a display device includes an organic insulating layer, a first lower electrode provided above the organic insulating layer, a second lower electrode provided above the organic insulating layer and spaced apart from the first lower electrode in a first direction, an inorganic insulating layer provided between the organic insulating layer and the first lower electrode and the second lower electrode, a rib layer having a first pixel aperture overlapping the first lower electrode and a second pixel aperture overlapping the second lower electrode, and a partition having a lower portion provided on the rib layer and having conductivity and an upper portion provided on the lower portion and protruding relative to side surfaces of the lower portion. The inorganic insulating layer has a first slit extending in a second direction intersecting the first direction. The partition has a second slit extending in the second direction and overlapping the first slit in plan view. The first slit and the second slit are located between the first lower electrode and the second lower electrode.

Embodiments can provide a display device capable of suppressing the degradation in display quality.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis and a Z-axis orthogonal to each other are described to facilitate understanding as needed. A direction along the X-axis is referred to as an X-direction (the first direction), a direction along the Y-axis is referred to as a Y-direction (the second direction), and a direction along the Z-axis is referred to as a Z-direction. In addition, viewing various elements parallel to the Z-direction is referred to as plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

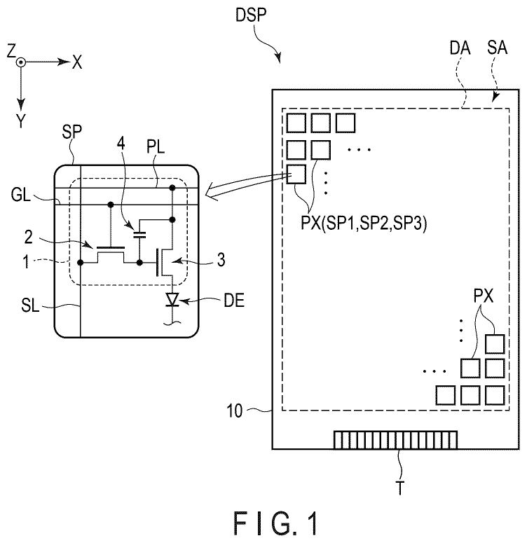

FIG. 1 is a view showing a configuration example of a display device DSP according to an embodiment. The display device DSP comprises an insulating substrate 10. The substrate 10 has a display area DA which displays an image and a surrounding area SA around the display area DA. The substrate 10 may be glass or a resinous film having flexibility.

In the present embodiment, the substrate 10 is rectangular as seen in plan view. The shape of the substrate 10 in plan view is not limited to a rectangle and may be another shape such as a square, a circle or an oval.

The display area DA comprises a plurality of pixels PX arranged in a matrix in the X-direction and the Y-direction. Each pixel PX includes a plurality of subpixels SP which display different colors. The present embodiment assumes a case where each pixel PX includes a red subpixel SP1, a green subpixel SP2, and a blue subpixel SP3. However, each pixel PX may include a subpixel SP that exhibits another color such as white in addition to the subpixels SP1, SP2, and SP3 or instead of one of the subpixels SP1, SP2, and SP3.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

The display area DA has a plurality of scanning lines GL each supplying the pixel circuit 1 of each subpixel SP with scanning signals, a plurality of signal lines SL each supplying the pixel circuit 1 of each subpixel SP with video signals, and a plurality of power lines PL. In the example of FIG. 1, the scanning lines GL and the power lines PL extend in the X-direction, and the signal lines SL extend in the Y-direction.

A gate electrode of the pixel switch 2 is connected to the scanning line GL. A source electrode of the pixel switch 2 is connected to the signal line SL. A drain electrode of the pixel switch 2 is connected to a gate electrode of the drive transistor 3 and a capacitor 4. A source electrode of the drive transistor 3 is connected to the power line PL and the capacitor 4. The drain electrode of the drive transistor 3 is connected to the display element DE.

The configuration of the pixel circuit 1 is not limited to the illustrated example. For example, the pixel circuit 1 may comprise more thin-film transistors and capacitors.

The display device DSP further comprises a terminal portion T provided in the surrounding area SA. For example, a flexible printed circuit is connected to the terminal portion T. The signals and voltage for driving the pixel circuit 1 are input to the display device DSP via these flexible printed circuit and terminal portion T.

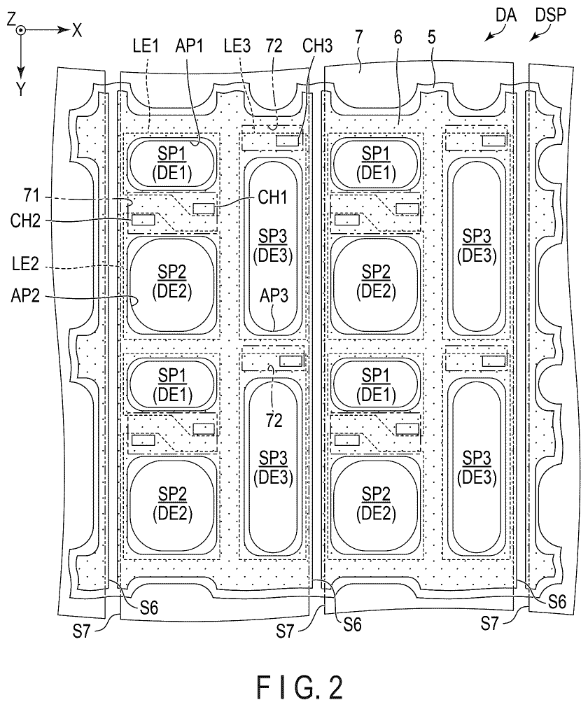

FIG. 2 is a schematic plan view showing an example of the layout of the subpixels SP1, SP2, and SP3. In the example of FIG. 2, a column in which the subpixels SP1 and SP2 are alternately arranged in the Y-direction and a column in which the plurality of subpixels SP3 are repeatedly arranged in the Y-direction are formed. These columns are alternately arranged in the X-direction.

The layout and the sizes of the subpixels SP1, SP2, and SP3 are not limited to the example of FIG. 2. Further, at least two of the subpixels SP1, SP2, and SP3 may have the same size.

A rib layer 5 is provided in the display area DA. The rib layer 5 has pixel apertures AP1, AP2 and AP3 in the subpixels SP1, SP2 and SP3, respectively. In the example of FIG. 2, the pixel aperture AP1 is smaller than the pixel aperture AP2, and the pixel aperture AP2 is smaller than the pixel aperture AP3. Thus, among the subpixels SP1, SP2, and SP3, the subpixel SP1 has the smallest aperture ratio, and the subpixel SP3 has the greatest aperture ratio.

A partition 6 is provided in the display area DA. The partition 6 is located above the rib layer 5 to entirely overlap the rib layer 5. In the example of FIG. 2, the partition 6 has a planar shape similar to that of the rib layer 5. In other words, the partition 6 has an aperture in each of the subpixels SP1, SP2, and SP3. From another viewpoint, the partition 6 has a grating shape in plan view and surrounds each of the pixel apertures AP1, AP2, and AP3.

As described in detail later, the partition 6 has a plurality of slits S6 (the second slits). In the example of FIG. 2, each of the slits S6 extends in the Y-direction. For example, the subpixels SP1, SP2 and SP3 constituting one pixel PX are provided between two slits S6 adjacent to each other in the X-direction.

The subpixel SP1 includes a display element DE1 including a lower electrode LE1 (the first lower electrode), which overlaps the pixel aperture AP1 (the first pixel aperture). The subpixel SP2 includes a display element DE2 including a lower electrode LE2, which overlaps the pixel aperture AP2. The subpixel SP3 includes a display element DE3 including a lower electrode LE3 (the second lower electrode), which overlaps the pixel aperture AP3 (the second pixel aperture). The lower electrodes LE1, LE2, and LE3 are spaced apart from one another.

The pixel circuit 1 (shown in FIG. 1) of the subpixels SP1, SP2, and SP3 are provided below the respective lower electrodes LE1, LE2, and LE3. The lower electrode LE1 is connected to the pixel circuit 1 of the subpixel SP1 through a contact hole CH1. The lower electrode LE2 is connected to the pixel circuit 1 of the subpixel SP2 through a contact hole CH2. The lower electrode LE3 is connected to the pixel circuit 1 of the subpixel SP3 through a contact hole CH3.

An inorganic insulating layer 7 is provided in the display area DA. The inorganic insulating layer 7 is located below the rib layer 5 and the partition 6. The inorganic insulating layer 7 overlaps the pixel apertures AP1, AP2, and AP3 in plan view.

The inorganic insulating layer 7 has apertures 71 and 72. The apertures 71 and 72 overlap the rib layer 5 and the partition 6 in plan view. The aperture 71 is located between the pixel aperture AP1 and the pixel aperture AP2 in the Y-direction. The aperture 72 is provided between two pixel apertures AP3 adjacent to each other in the Y-direction. The contact holes CH1 and CH2 overlap the aperture 71 in plan view. The contact hole CH3 overlaps the aperture 72 in plan view.

As described in detail later, the inorganic insulating layer 7 has a plurality of slits S7 (the first slits). In the example of FIG. 2, each of the slits S7 extends in the Y-direction. Each of the slits S7 overlaps each of the slits S6 in plan view.

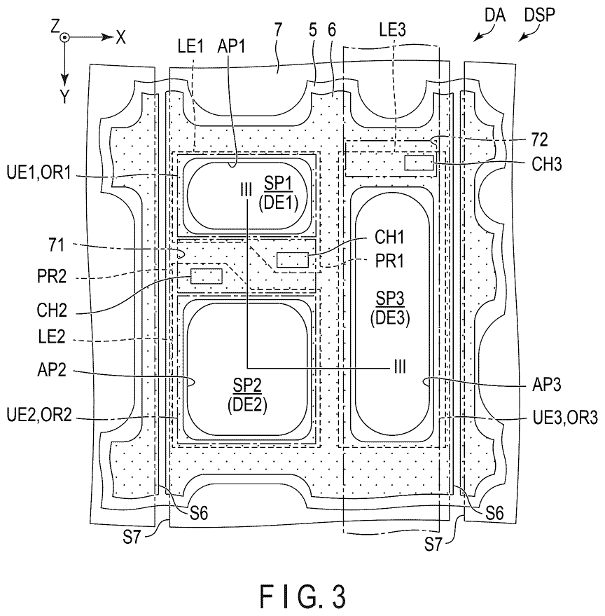

FIG. 3 is a schematic plan view showing the subpixels SP1, SP2, and SP3 shown in FIG. 2 in an enlarged manner. The display element DE1 of the subpixel SP1 further includes an upper electrode UE1 (the first upper electrode) and an organic layer OR1 (the first organic layer) that overlap the pixel aperture AP1. The display element DE2 of the subpixel SP2 further includes an upper electrode UE2 and an organic layer OR2 that overlap the pixel aperture AP2. The display element DE3 of the subpixel SP3 further includes an upper electrode UE3 (the second upper electrode) and an organic layer OR3 (the second organic layer) that overlap the pixel aperture AP3. The upper electrodes UE1, UE2, and UE3 and the organic layers OR1, OR2, and OR3 overlap the inorganic insulating layer 7 in plan view.

In the example of FIG. 3, the lower electrode LE1 has a protrusion portion PR1 having a protrusion shape extending toward the lower electrode LE2, and the lower electrode LE2 has a protrusion portion PR2 having a protrusion shape extending toward the lower electrode LE1. The protrusion portions PR1 and PR2 overlap the aperture 71 in plan view. The contact holes CH1 and CH2 overlap the protrusion portions PR1 and PR2, respectively in plan view. The lower electrodes LE1 and LE2 may not have the respective protrusion portions PR1 and PR2. In addition, the lower electrode LE3 may have a protrusion portion overlapping the contact hole CH3 in plan view.

In the example of FIG. 3, the outer shapes of the lower electrodes LE1, LE2, and LE3 are indicated by dotted lines, and the outer shapes of the organic layers OR1, OR2, and OR3 and the upper electrodes UE1, UE2, and UE3 are indicated by one-dot chain lines. The outer shape of each of the lower electrodes, the organic layers, and the upper electrodes illustrated in the figure does not necessarily reflect the accurate shape.

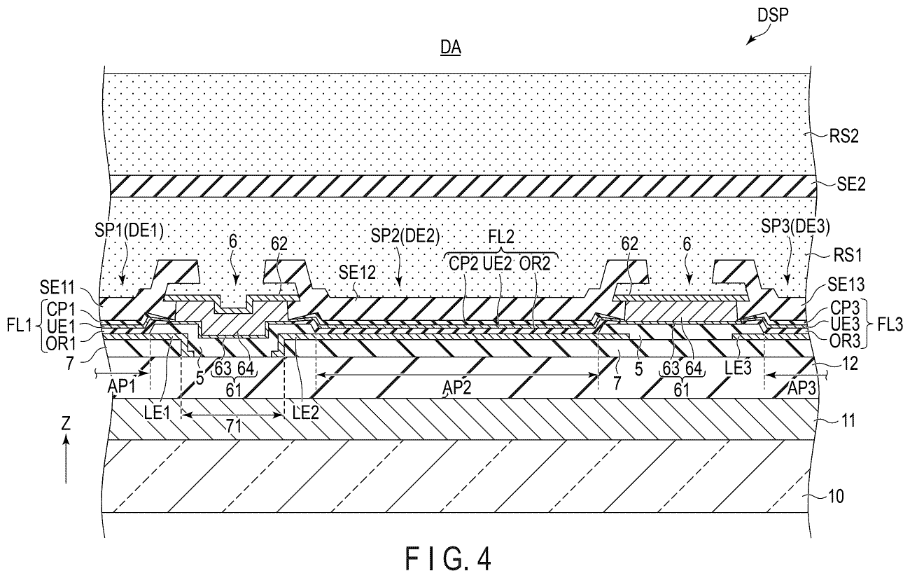

FIG. 4 is a schematic cross-sectional view of the display device DSP along the III-III line of FIG. 3. A circuit layer 11 is provided on the substrate 10 described above. The circuit layer 11 includes various circuits and lines such as the pixel circuit 1, the scanning lines GL, the signal lines SL, and the power lines PL shown in FIG. 1. The circuit layer 11 is provided below the organic insulating layer 12 and is covered with the organic insulating layer 12. The organic insulating layer 12 functions as a planarization film which planarizes irregularities formed by the circuit layer 11.

The lower electrodes LE1, LE2, and LE3 are provided above the organic insulating layer 12. The inorganic insulating layer 7 is provided between the organic insulating layer 12 and the respective lower electrodes LE1, LE2, and LE3. The lower electrodes LE1 and LE2 contact the organic insulating layer 12 in the aperture 71. The inorganic insulating layer 7 is thicker than the lower electrodes LE1, LE2, and LE3.

The rib layer 5 is provided on the organic insulating layer 12, the inorganic insulating layer 7, and the lower electrodes LE1, LE2, and LE3. The rib layer 5 contacts the organic insulating layer 12 between the lower electrodes LE1 and LE2 and contacts the inorganic insulating layer 7 between the lower electrodes LE2 and LE3. End portions of the lower electrodes LE1, LE2, and LE3 are covered with the rib layer 5.

The partition 6 has a conductive lower portion 61 provided on the rib layer 5 and an upper portion 62 provided on the lower portion 61. The upper portion 62 has a width greater than that of the lower portion 61. This configuration allows the both end portions of the upper portion 62 to protrude relative to the side surfaces of the lower portion 61. This shape of the partition 6 is called an overhang shape.

In the example of FIG. 4, the lower portion 61 has a conductive bottom layer 63 provided on the rib layer 5 and a stem layer 64 provided on the bottom layer 63. For example, the bottom layer 63 is thinner than the stem layer 64. In the example of FIG. 4, the both end portions of the bottom layer 63 protrude relative to the side surfaces of the stem layer 64. The upper portion 62 is provided on the stem layer 64. The aperture 71 overlaps the bottom layer 63 in plan view.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 contact the side surface of the lower portion 61 of the partition 6.

The display element DE1 includes a cap layer CP1 covering the upper electrode UE1. The display element DE2 includes a cap layer CP2 covering the upper electrode UE2. The display element DE3 includes a cap layer CP3 covering the upper electrode UE3. The cap layers CP1, CP2, and CP3 function as optical adjustment layers that improve the extraction efficiency of light emitted from the organic layers OR1, OR2, and OR3, respectively.

In the following explanation, a multilayer body including the organic layer OR1, the upper electrode UE1, and the cap layer CP1 is called a stacked film FL1, a multilayer body including the organic layer OR2, the upper electrode UE2, and the cap layer CP2 is called a stacked film FL2, and a multilayer body including the organic layer OR3, the upper electrode UE3, and the cap layer CP3 is called a stacked film FL3.

Sealing layers SE11, SE12, and SE13, which respectively cover the stacked films FL1, FL2, and FL3 are respectively provided in the subpixels SP1, SP2, and SP3. The sealing layer SE11 continuously covers the cap layer CP1 and the partition 6 around the subpixel SP1. The sealing layer SE12 continuously covers the cap layer CP2 and the partition 6 around the subpixel SP2. The sealing layer SE13 continuously covers the cap layer CP3 and the partition 6 around the subpixel SP3.

In the example of FIG. 4, the sealing layer SE11 on the partition 6 between the subpixels SP1 and SP2 is spaced apart from the sealing layer SE12 on this partition 6. The sealing layer SE12 on the partition 6 between the subpixels SP2 and SP3 is spaced apart from the sealing layer SE13 on this partition 6. Two of the sealing layers SE11, SE12 and SE13 may contact each other above the partition 6.

For example, gaps are formed between the respective sealing layers SE11, SE12, and SE13 and the upper portion 62 of the partition 6. The stacked films FL1, FL2 and FL3 may be provided in at least part of these gaps.

The sealing layers SE11, SE12, and SE13 are covered with a resin layer RS1. The resin layer RS1 is covered with the sealing layer SE2. The sealing layer SE2 is covered with a resin layer RS2. The resin layers RS1 and RS2 and the sealing layer SE2 are continuously provided in at least the entire display area DA and partly extend in the surrounding area SA as well.

A cover member such as a polarizer, a touch panel, a protective film, or a cover glass may be further provided above the resin layer RS2. This cover member may be attached to the resin layer RS2 via, for example, an adhesive layer such as an optical clear adhesive (OCA).

The organic insulating layer 12 is formed of an organic insulating material such as a polyimide. Each of the rib layer 5, the inorganic insulating layer 7, and the sealing layers SE11, SE12, SE13, and SE2 is formed of an inorganic insulating material such as a silicon nitride (SiNx), a silicon oxide (SiOx), a silicon oxynitride (SiON), or an aluminum oxide (Al₂O₃). As an example, the inorganic insulating layer 7 is formed of the same transparent material as the rib layer 5. Each of the resin layers RS1 and RS2 is formed of, for example, a resinous material (organic insulating materials) such as an epoxy resin or an acrylic resin.

Each of the lower electrodes LE1, LE2, and LE3 has a reflective layer formed of, for example, silver, and a pair of conductive oxide layers covering the upper and lower surfaces of the reflective layer. Each of the conductive oxide layers can be formed of, for example, a transparent conductive oxide such as an indium tin oxide (ITO), an indium zinc oxide (IZO), or an indium gallium zinc oxide (IGZO).

The upper electrodes UE1, UE2, and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

The organic layers OR1, OR2, and OR3 are configured to emit light in different colors. For example, each of the organic layers OR1, OR2, and OR3 has a structure in which a hole injection layer, a hole transport layer, an electron blocking layer, a light emitting layer, a hole blocking layer, an electron transport layer, and an electron injection layer are stacked in this order in the Z-direction. Each of the organic layers OR1, OR2, and OR3 may have other structures such as a tandem structure having a plurality of light emitting layers.

Each of the cap layers CP1, CP2, and CP3 has, for example, a multilayer structure in which a plurality of transparent layers are stacked. These transparent layers could have a layer formed of an inorganic material and a layer formed of an organic material. The transparent layers have refractive indices different from one another. For example, the refractive indices of these transparent layers are different from the refractive indices of the upper electrodes UE1, UE2, and UE3 and the refractive indices of the sealing layers SE11, SE12, and SE13. At least one of the cap layers CP1, CP2, and CP3 may be omitted.

For example, each of the bottom layer 63 and the stem layer 64 of the partition 6 is formed of a metal material. For the metal material of the bottom layer 63, for example, molybdenum (Mo), titanium (Ti), a titanium nitride (TiN), a molybdenum-tungsten alloy (MoW), or a molybdenum-niobium alloy (MoNb) can be used. For the metal material of the stem layer 64, for example, aluminum (Al), an aluminum-neodymium alloy (AlNd), an aluminum-yttrium alloy (AlY), or an aluminum-silicon alloy (AlSi) can be used. For example, at least one of the bottom layer 63 and the stem layer 64 may have a stacked layer structure in which a plurality of layers are stacked. The stem layer 64 may have a layer formed of an insulating material.

For example, the upper portion 62 of the partition 6 has a stacked layer structure of a lower layer formed of a metal material and an upper layer formed of a conductive oxide. For the metal material forming the lower layer, for example, titanium, a titanium nitride, molybdenum, tungsten, a molybdenum-tungsten alloy, or a molybdenum-niobium alloy may be used. For the conductive oxide forming the upper layer, for example, ITO or IZO may be used. The upper portion 62 may have a single-layer structure of a metal material. The upper portion 62 may further have a layer formed of an insulating material.

Common voltage is applied to the partition 6. This common voltage is applied to each of the upper electrodes UE1, UE2, and UE3 that contact the side surfaces of the lower portions 61. Pixel voltages according to the video signals of the signal lines SL are applied to the lower electrodes LE1, LE2, and LE3 through the respective pixel circuits 1 provided in the subpixels SP1, SP2, and SP3.

The organic layers OR1, OR2, and OR3 emit light in response to the application of a voltage. More specifically, when a potential difference is formed between the lower electrode LE1 and the upper electrode UE1, the light emitting layer of the organic layer OR1 emits light in the red wavelength range. When a potential difference is formed between the lower electrode LE2 and the upper electrode UE2, the light emitting layer of the organic layer OR2 emits light in the green wavelength range. When a potential difference is formed between the lower electrode LE3 and the upper electrode UE3, the light emitting layer of the organic layer OR3 emits light in the blue wavelength range.

As another example, the light emitting layers of the organic layers OR1, OR2, and OR3 may emit light of the same color (for example, white). In this case, the display device DSP may comprise a color filter that converts light emitted from the light emitting layers into light of the colors corresponding to those of the subpixels SP1, SP2, and SP3. Further, the display device DSP may have a layer including quantum dots that are excited by the light emitted from the light emitting layers to generate light of the colors corresponding to those of the subpixels SP1, SP2, and SP3.

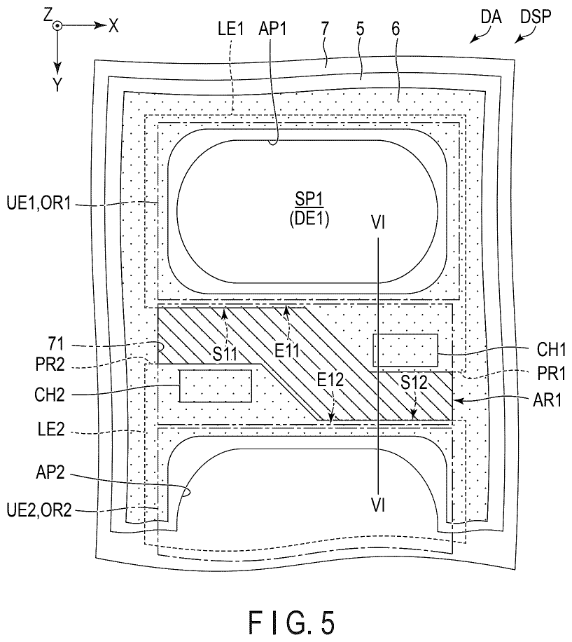

FIG. 5 is a schematic plan view showing the vicinities of the contact holes CH1 and CH2 shown in FIG. 3 in an enlarged manner. As shown in FIG. 5, the display area DA has a first area AR1 corresponding to an area located between the lower electrodes LE1 and LE2 and overlapping the aperture 71. That is, the first area AR1 does not overlap the lower electrodes LE1 and LE2 and the inorganic insulating layer 7 in plan view. The partition 6 covers the first area AR1 in plan view. In the example of FIG. 5, the first area AR1 overlaps the protrusion portions PR1 and PR2 in plan view. In the example of FIG. 5, the first area AR1 is indicated by hatch lines.

The lower electrode LE1 has a first side S11. The lower electrode LE2 has a second side S12. The first side S11 and the second side S12 extend in the X-direction. The first side S11 is located between the pixel aperture AP1 and the contact hole CH2 in the Y-direction. In the example shown in FIG. 5, the first side S11 is located between the pixel aperture AP1 and the contact hole CH1 in the Y-direction. The second side S12 is located between the pixel aperture AP2 and the contact hole CH1 in the Y-direction. In the example shown in FIG. 5, the second side S12 is located between the pixel aperture AP2 and the contact hole CH2 in the Y direction.

The protrusion portion PR1 protrudes from the first side S11 toward the lower electrode LE2 and overlaps the contact hole CH1. The protrusion portion PR2 protrudes from the second side S12 toward the lower electrode LE1 and overlaps the contact hole CH2. In the example of FIG. 5, each of the protrusion portions PR1 and PR2 has a trapezoid shape.

The aperture 71 has a first aperture edge portion E11 and a second aperture edge portion E12. The first aperture edge portion E11 extends in the X-direction. The second aperture edge portion E12 faces the first aperture edge portion E11 in the Y-direction and extends in the X-direction.

The first aperture edge portion E11 is located between the contact hole CH1 and the pixel aperture AP1 in the Y-direction and overlaps the partition 6 in plan view. In the example shown in FIG. 5, the first aperture edge portion E11 is located between the first side S11 and the pixel aperture AP1 in the Y-direction. The second aperture edge portion E12 is located between the contact hole CH2 and the pixel aperture AP2 in the Y-direction and overlaps the partition 6 in plan view. In the example shown in FIG. 5, the second aperture edge portion E12 is located between the second side S12 and the pixel aperture AP2 in the Y-direction. The first aperture edge portion E11 may be provided between the first side S11 and the contact hole CH1 in the Y-direction. The second aperture edge portion E12 may be provided between the second side S12 and the contact hole CH2 in the Y-direction.

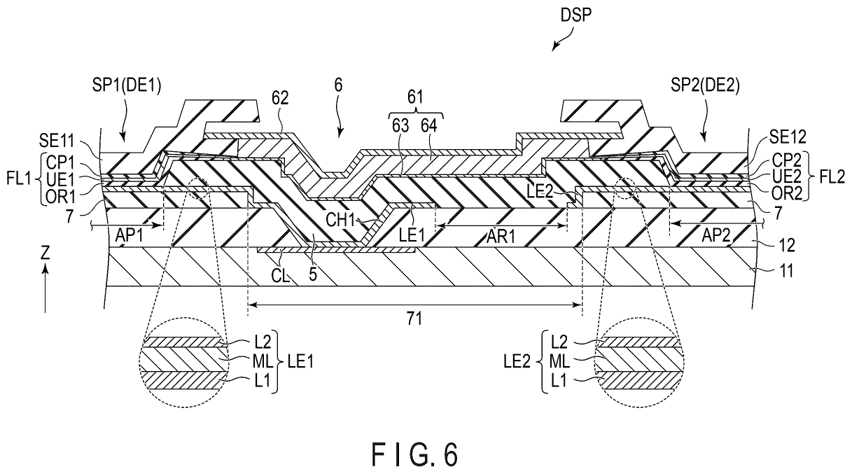

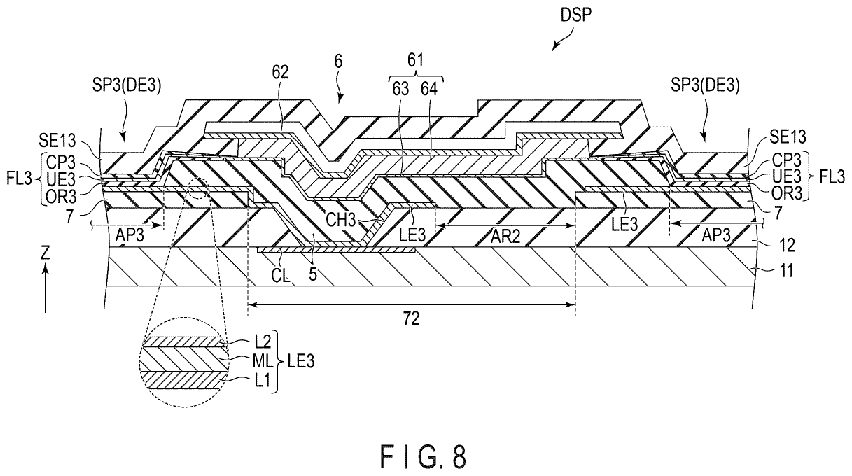

FIG. 6 is a schematic cross-sectional view of the display device DSP along the VI-VI line of FIG. 5. FIG. 6 and FIG. 8 to be described omit the illustration of the substrate 10, the resin layers RS1 and RS2, and the sealing layer SE2 shown in FIG. 4. The rib layer 5 contacts the organic insulating layer 12 in the aperture 71. In the example shown in FIG. 6, the rib layer 5 contacts the organic insulating layer 12 in the first area AR1. The bottom layer 63 covers the first area AR1 in plan view.

The contact hole CH1 is provided on the organic insulating layer 12 and penetrates the organic insulating layer 12. The lower electrode LE1 contacts a conductive layer CL included in the circuit layer 11 through the contact hole CH1. The conductive layer CL corresponds to the source electrode or the drain electrode of the drive transistor 3 shown in FIG. 1.

As shown in an enlarged manner in lower part of FIG. 6, each of the lower electrodes LE1 and LE2 has a metal layer ML, a first layer L1 covering the lower surface of the metal layer ML, and a second layer L2 covering the upper surface of the metal layer ML. For example, the metal layer ML is a reflective layer formed of silver. For example, each of the first layer L1 and the second layer L2 is a conductive oxide layer formed of a transparent conductive oxide such as ITO.

For example, the second layer L2 is thinner than each of the first layer L1 and the metal layer ML. The first layer L1 is thinner than the metal layer ML or is as thick as the metal layer ML. The relationship among the thicknesses of the metal layer ML, the first layer L1, and the second layer L2 are not limited to the above examples. For example, the second layer L2 may be thicker than each of the first layer L1 and the metal layer ML.

Though not illustrated, the contact hole CH2 shown in FIG. 5 is provided on the organic insulating layer 12 and penetrates the organic insulating layer 12, as in the case of the contact hole CH1. The lower electrode LE2 contacts the conductive layer CL included in the circuit layer 11 through the contact hole CH2.

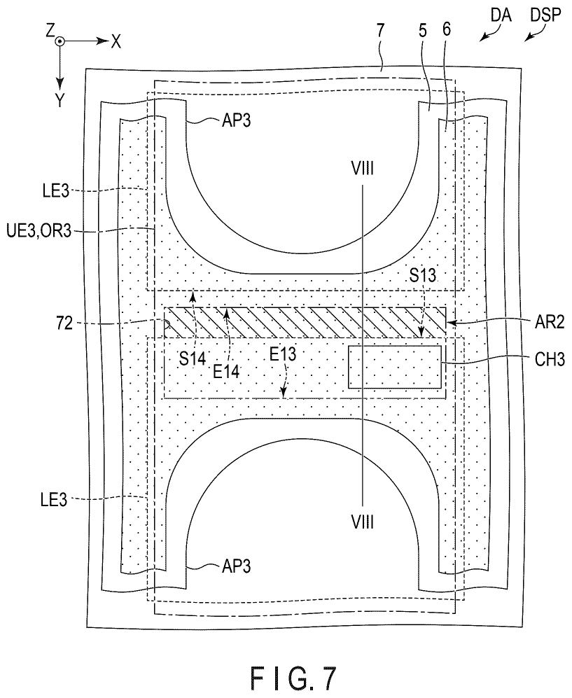

FIG. 7 is a schematic plan view showing the vicinity of the contact hole CH3 shown in FIG. 3 in an enlarged manner. As shown in FIG. 7, the display area DA has a second area AR2, which corresponds to an area located between two lower electrodes LE3 adjacent to each other in the Y-direction and overlapping the aperture 72. That is, the second area AR2 does not overlap the lower electrode LE3 and the inorganic insulating layer 7. The partition 6 covers the second area AR2 in plan view. In the example of FIG. 7, the second area AR2 is indicated by hatch lines.

The lower electrode LE3 has a third side S13 and a fourth side S14. The third side S13 and the fourth side S14 extend in the X-direction. The third side S13 corresponds to a side on which the contact hole CH3 is located, among the sides constituting the lower electrode LE3. The fourth side S14 corresponds to a side located on the opposite side of the third side S13 with respect to the pixel aperture AP3 in the Y-direction.

The aperture 72 has a third aperture edge portion E13 and a fourth aperture edge portion E14. The third aperture edge portion E13 extends in the X-direction. The fourth aperture edge portion E14 faces the third aperture edge portion E13 in the Y-direction and extends in the X-direction.

The third aperture edge portion E13 is located between the contact hole CH3 and the pixel aperture AP3 in the Y-direction and overlaps the partition 6 in plan view. In the example shown in FIG. 7, the third aperture edge portion E13 is located between the third side S13 and the pixel aperture AP3 in the Y-direction. The fourth aperture edge portion E14 overlaps the partition 6 in plan view. In the example shown in FIG. 7, the fourth aperture edge portion E14 is located between the third side S13 and the fourth side S14 in the Y-direction. The third aperture edge portion E13 may be located between the third side S13 and the fourth side S14 in the Y-direction. The fourth aperture edge portion E14 may be located between the fourth side S14 and the pixel aperture AP3 in the Y-direction.

FIG. 8 is a schematic cross-sectional view of the display device DSP along the VIII-VIII line of FIG. 7. The lower electrode LE3 contacts the organic insulating layer 12 in the aperture 72. The aperture 72 overlaps the bottom layer 63 of the partition 6 in plan view. The rib layer 5 contacts the organic insulating layer 12 in the aperture 72. In the example shown in FIG. 8, the rib layer 5 contacts the organic insulating layer 12 in the second area AR2. The bottom layer 63 covers the second area AR2 in plan view.

The contact hole CH3 is provided on the organic insulating layer 12 and penetrates the organic insulating layer 12. The lower electrode LE3 contacts the conductive layer CL included in the circuit layer 11 through the contact hole CH3.

As in the case of the lower electrodes LE1 and LE2, the lower electrode LE3 has the metal layer ML, the first layer L1 covering the lower surface of the metal layer ML, and the second layer L2 covering the upper surface of the metal layer ML.

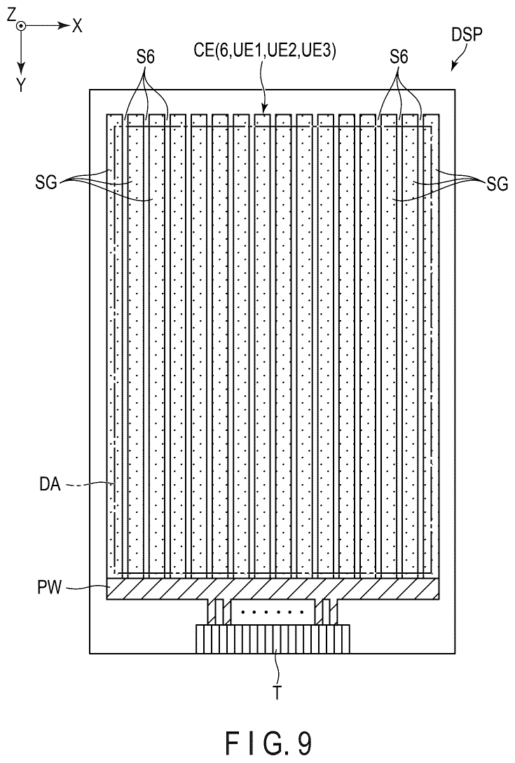

FIG. 9 is a schematic plan view showing some elements of the display device DSP. The partition 6 and the upper electrodes UE1, UE2 and UE3 constitute a common electrode CE, which applies common voltage to the display elements DE1, DE2 and DE3. The common electrode CE is, for example, in a rectangular shape extending in the Y-direction and entirely overlaps the display area DA.

The common electrode CE has the plurality of slits S6. At least one end of each of the slits S6 reaches the outer edge of the common electrode CE (the outline in plan view). In the example of FIG. 9, the both ends of the slit S6 reach the outer edge of the common electrode CE. By this configuration, the common electrode CE is divided into a plurality of segments SG spaced apart from each other via each of the slits S6.

In the example of FIG. 9, each of the slits S6 extends in the Y-direction. The number of the slits S6 provided in the common electrode CE is not particularly limited. For example, at least 15 slits S6 are provided, thereby dividing the common electrode CE into at least 16 segments.

The intervals of the slits S6 in the X-direction are, for example, constant. In this case, the widths of the segments SG in the X-direction are also constant. As another example, the interval of the slits S6 or the widths of the segments SG may not be constant.

Each of the segments SG is connected to a power supply line PW provided in the surrounding area SA. The power supply line PW is connected to the terminal portion T. Common voltage is applied to each of the segments SG from the terminal portion T via the power supply line PW. In the example of FIG. 9, the power supply line PW is connected to the end portion of each of the segments SG that are in the terminal portion T side. The configuration is not limited to this example. The power supply line PW may be provided to entirely surround the segments SG.

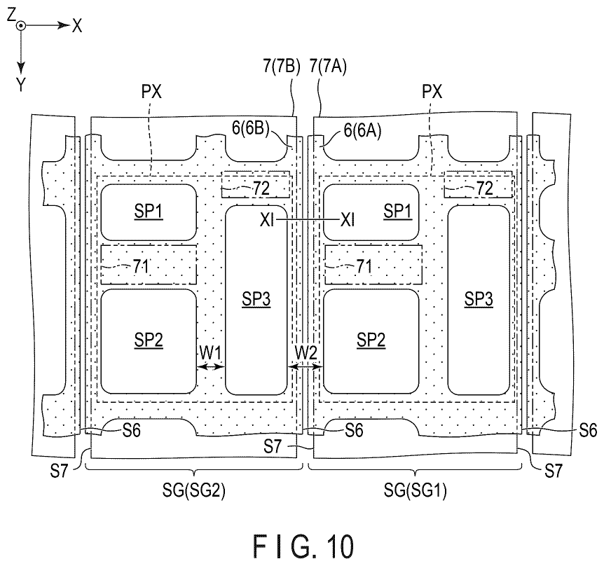

FIG. 10 is a plan view showing an example of the relationships among the slits S6 of the partition 6 and the slits S7 of the inorganic insulating layer 7.

The slits S6 are provided in portions extending parallel to the Y-direction in the partition 6. More specifically, in the example of FIG. 10, each of the slits S6 is provided in the portion located between the pixels PX that are adjacent to each other in the X-direction in the partition 6. That is, each of the slits S6 passes between one of the subpixel SP1 and SP2 adjacent to each other in the X direction and the other subpixel SP3. However, the form of the slits S6 is not limited to this example. For example, two or more pixels PX may be arranged between adjacent slits S6 in the X-direction.

The slit S7 is provided on the portion that overlaps the slit S6 of the inorganic insulating layer 7. More specifically, in the example of FIG. 10, each of the slits S7 is provided in the portion located between the pixels PX that are adjacent to each other in the X-direction in the inorganic insulating layer 7, as in the case of the slits S6. That is, each of the slits S7 passes between one of the subpixels SP1 and SP2 adjacent to each other in the X-direction and the other subpixel SP3. However, the form of the slit S7 is not limited to this example. For example, two or more pixels PX arranged in the X-direction may be located between adjacent slits S7. For example, two or more slits S6 arranged in the X-direction may be located between adjacent slits S7. The slit S7 may reach the outer edge of the inorganic insulating layer 7, dividing the inorganic insulating layer 7 into a plurality of segments. The slits S7 may not be continuous. In this case, the slit S7 does not divide the inorganic insulating layer 7 into a plurality of segments.

For example, in the pixel PX, the width in the X-direction of the partition 6 between the subpixels SP1 and SP2 and the subpixel SP3 is defined as a width W1, and the width in the X-direction of the partition 6 between two pixels PX adjacent to each other in the X-direction is defined as a width W2. The Width W2 corresponds to the sum of the widths in the X-direction of the partitions 6A and 6B and the slit S6.

In the example shown in FIG. 10, the width W2 is greater than the width W1 (W2>W1). The magnitude relationship of the widths W1 and W2 are not limited to this example. For example, the widths W1 and W2 may be equivalent to each other (W1=W2).

As shown in FIG. 10, the following focuses on two segments SG1 and SG2 divided by the slit S6. The segment SG1 has a partition 6A along the slit S6. The segment SG2 has a partition 6B along the slit S6. Both of the partitions 6A and 6B extend in the Y-direction.

The inorganic insulating layer 7 has an inorganic insulating layer 7A overlapping the partition 6A and an inorganic insulating layer 7B overlapping the partition 6B.

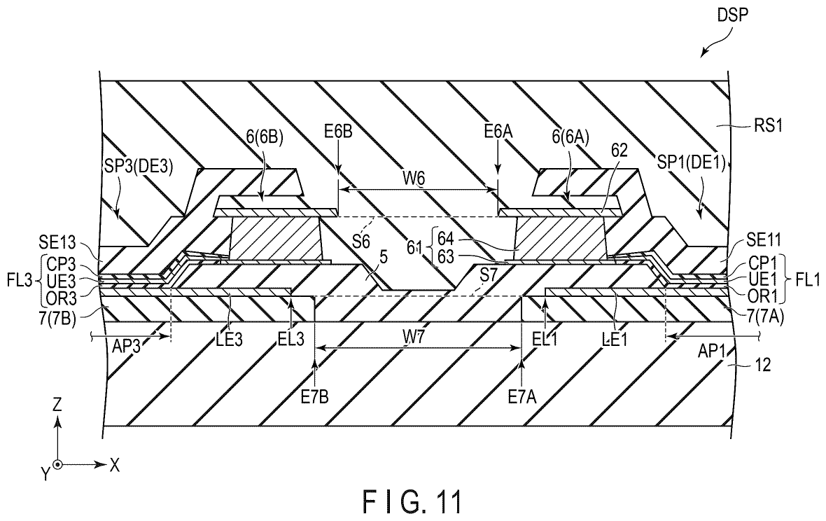

FIG. 11 is a schematic cross-sectional view of the display device DSP along the XI-XI line of FIG. 10. FIG. 11 and FIG. 14 to FIG. 17 omit the illumination of the elements located under the organic insulating layer 12 and the elements located above the resin layer RS1.

As shown in FIG. 11, each of the partitions 6A and 6B has the lower portion 61 and the upper portion 62. Further, in each of the partitions 6A and 6B, the lower portion 61 has the bottom layer 63 and the stem layer 64. Each of the partitions 6A and 6B has an overhang shape in which the both end portions of the upper portion 62 protrude relative to the side surfaces of the lower portion 61 (the side surfaces of the stem layer 64). In addition, in the example of FIG. 11, in the slit S6, the end portion of the bottom layer 63 of each of the partitions 6A and 6B protrudes relative to the side surface of the stem layer 64.

Each of the slits S6 and S7 is located between the lower electrodes LE1 and LE3. In the example of FIG. 11, the slit S6 is filled with the resin layer RS1. In the slit S6, the resin layer RS1 contacts the rib layer 5. In the example of FIG. 11, the slit S7 is filled with the rib layer 5. In the slit S7, the rib layer 5 contacts the organic insulating layer 12.

In the example of FIG. 11, the end portion of the sealing layer SE11 of the subpixel SP1 is located above the partition 6A. Further, the end portion of the sealing layer SE13 of the subpixel SP3 is located above the partition 6B.

The inorganic insulating layer 7A has an end portion E7A (the first end portion) facing the slit S7. In the example of FIG. 11, the end portion E7A overlaps the partition 6A in plan view, but does not overlap the slit S6 in plan view. The inorganic insulating layer 7B has an end portion E7B facing the slit S7. In the example of FIG. 11, the end portion E7B overlaps the partition 6B in plan view, but does not overlap the slit S6 in plan view. The end portions E7A and E7B are covered with the rib layer 5.

The upper portion 62 of the partition 6A has an end portion E6A (the second end portion) facing the slit S6. In the example of FIG. 11, the end portion E7A is retracted relative to the end portion E6A. That is, the end portion E6A overlaps the slit S7 in plan view, but does not overlap the inorganic insulating layer 7A in plan view.

The upper portion 62 of the partition 6B has an end portion E6B facing the slit S6. In the example of FIG. 11, the end portion E7B is retracted relative to the end portion E6B. That is, the end portion E6B overlaps the slit S7 in plan view, but does not overlap the inorganic insulating layer 7B in plan view. The end portions E6A and E6B are covered with the resin layer RS1.

The slit S7 has a width W7 (the first width) along the X-direction. The slit S6 has a width W6 (the second width) along the X-direction. In the example of FIG. 11, the width W7 is greater than the width W6 (W7>W6). Thus, the partitions 6A and 6B overlap the slit S7 in plan view. The inorganic insulating layers 7A and 7B do not overlap the slit S6 in plan view.

The lower electrode LE1 has an end portion EL1 (the third end portion) overlapping the partition 6A in plan view. In the example of FIG. 11, the end portion EL1 is retracted relative to the end portion E7A of the inorganic insulating layer 7A. The lower electrode LE3 has an end portion EL3 overlapping the partition 6B in plan view. In the example of FIG. 11, the end portion EL3 is retracted relative to the end portion E7B of the inorganic insulating layer 7B. The end portions EL1 and EL3 do not overlap the slit S6 in plan view. That is, the lower electrodes LE1 and LE3 do not overlap the slit S6 in plan view. The end portions EL1 and EL3 are covered with the rib layer 5. Though not illustrated, the lower electrode LE2 is configured in the same manner as the lower electrodes LE1 and LE3 and does not overlap the slit S6.

In the example of FIG. 11, the end portions E6A, E7A, and EL1 are respectively positioned symmetrically with the end portions E6B, E7B, and EL3 across an axis parallel to the Z-direction.

In the present embodiment, the inorganic insulating layer 7 is provided between the organic insulating layer 12 and the respective lower electrodes LE1, LE2, and LE3. For example, a display device DSP that comprises no inorganic insulating layer 7 and has a portion overlapping the pixel aperture AP1 and having a defective such as a pinhole of the lower electrode LE1 may cause moisture contained in the organic insulating layer 12 to infiltrate the organic layer OR1 through the defective. The organic layer OR1 typically has low moisture resistances. Thus, infiltration of moisture into the organic layer OR1 may cause display failures such as dead pixels.

In contrast, the present embodiment includes the inorganic insulating layer 7 that hardly allows the infiltration of moisture. Thus, for example, even when the portion overlapping the pixel aperture AP1 of the lower electrode LE1 has a defective such as a pinhole, this inorganic insulating layer 7 can suppress the infiltration of moisture into the defective. This can suppress display failures and degradation in display quality in the display device DSP.

An example of a manufacturing method of the display device DSP performs patterning on the lower electrodes LE1, LE2, and LE3 and then performs heat treatment to crystallize ITO contained in the second layer L2 of the lower electrodes LE1, LE2, and LE3. The heat treatment allows the organic insulating layer 12 to have a high temperature and to evaporate moisture contained therein.

The present embodiment has the first area AR1 and the second area AR2, which do not overlap the lower electrodes LE1, LE2, and LE3 and the inorganic insulating layer 7. Moisture of the organic insulating layer 12 evaporated in this heat treatment passes through the first area AR1 and the second area AR2 and then is discharged to the atmosphere. This reduces the amount of moisture in the organic insulating layer 12, further suppressing display failures caused by the moisture.

In the present embodiment, each of the apertures 71 and 72 of the inorganic insulating layer 7 overlaps the rib layer 5 formed of an inorganic material. Thus, the rib layer 5 suppresses the infiltration of moisture into the organic layers OR1, OR2, and OR3 through the apertures 71 and 72. This can suppress display failures and degradation in display quality in the display device DSP.

The present embodiment has the rib layer 5 contacting the organic insulating layer 12 in the first area AR1 and the second area AR2. Thus, the rib layer 5 suppresses the infiltration of moisture into the organic layers OR1, OR2, and OR3 through the first area AR1 and the second area AR2. This can suppress display failures and degradation in display quality in the display device DSP.

When an area in which moisture contained in the organic insulating layer 12 is discharged in the above heat treatment is small, discharge amount of evaporated moisture may be insufficient, which has a risk of forming a gap between the organic insulating layer 12 and the inorganic insulating layer 7. To address this, the present embodiment has the slit S7 of the inorganic insulating layer 7, the slit S7 overlapping the slit S6 of the partition 6. Moisture of the organic insulating layer 12 evaporated in this heat treatment passes through the slit S7 in addition to the first area AR1 and the second area AR2 and then is discharged to the atmosphere. This enlarges an area in which moisture contained in the organic insulating layer 12 is discharged, increasing the discharge amount of the moisture. This suppresses the formation of the gap due to insufficient discharge amount of the moisture.

Each of the slits S6 of the partition 6 is located between the pixels PX adjacent to each other in the X-direction. Further, the width W2 in the X-direction of the partition 6 between the pixels PX adjacent to each other in the X-direction is greater than the width W1 in the X-direction of the partition 6 extending in the Y-direction in the pixel PX. As in this configuration, placing the slit S7 at the position overlapping the partition 6 extending in the Y-direction in the pixel PX can ensure a greater width W7 of the slit S7 than placing the slit S7 at the position overlapping the slit S6 between the adjacent pixels PX.

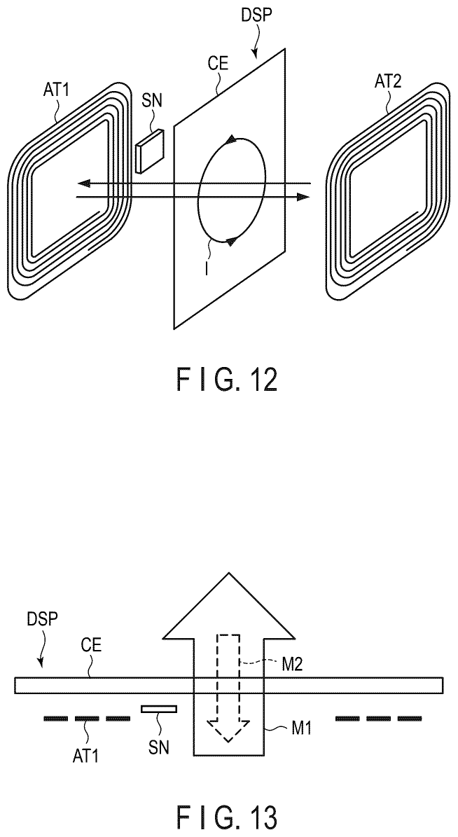

FIG. 12 and FIG. 13 are diagrams for explaining an effect of the slits S6 of the partition 6. An electronic device on which the display device DSP is mounted may comprise an antenna AT1 for near field communication (NFC). For example, the antenna AT1 is placed to face the rear side of the display device DSP (the lower surface of the substrate 10 shown in FIG. 4) and wirelessly communicates with an antenna AT2 of another electronic device through the display device DSP.

A magnetic field M1 formed by the antenna AT1 generates an eddy current I in the common electrode CE at the time of wireless communication between the antennas AT1 and AT2. The eddy current I forms a magnetic field M2, which negates the magnetic field M1 and attenuates the signal strength. Thus, wireless communication performed via the display device DSP could result in a decrease in the communication sensitivity. In particular, the resistance of the common electrode CE becomes low in cases where the partition 6 mainly formed of a metal material and having a grating shape is formed in the entire display area DA. This generates a large eddy current I and a strong magnetic field M2 in association with it, making the communication sensitivity easily decreased.

To the contrary, in the present embodiment, the common electrode CE is divided into the plurality of segments SG by the slits S6. This configuration prevents a large eddy current from being easily generated in the common electrode CE, suppressing the decrease in communication sensitivity. An eddy current could be generated in each segment SG. However, the adverse effect to communication sensitivity of this eddy current is smaller than that of the eddy current I generated in the entire common electrode CE that is not divided.

Electronic devices on which the display device DSP is mounted may comprise an optical sensor SN such as an illumination sensor, which detects external light. When the optical sensor SN is provided on the rear side of the display device DSP, the display device DSP needs to have a light transmitting property.

However, each of the lower electrodes LE1, LE2 and LE3 includes the metal layer ML that is a reflective layer. In addition, the partition 6, that is at least partly formed of a metal material, has a light-shielding property. For this reason, the light made incident on the display surface of the display device DSP could be mostly reflected or blocked without being transmitted to the rear side.

To the contrary, when the slits S6 are provided in the partition 6 as in the present embodiment, part of the light made incident on the display surface is transmitted to the rear side of the display device DSP through the slits S6. This configuration can enhance the light transmitting property of the display device DSP. Further, in cases where the lower electrodes LE1, LE2, and LE3 overlap the slits S6, light passing through the slit S6 is reflected by the reflective layers in the lower electrodes LE1, LE2, and LE3. This has the risk of decreasing the light transmitting property. The lower electrodes LE1, LE2, and LE3 of the present embodiment do not overlap the slits S6 in plan view. Thus, the present embodiment can increase the light transmitting property of the display device DSP.

Further, when the inorganic insulating layer 7 is placed on an optical path passing through the slit S6, the light transmitting property may decrease. In the present embodiment, the end portions E7A and E7B of the inorganic insulating layer 7 are retracted relative to the end portions E6A and E6B of the partition 6. That is, the inorganic insulating layer 7 is not placed on the optical path passing through the slit S6. This configuration can suppress the decrease in the light transmitting property of the display device DSP.

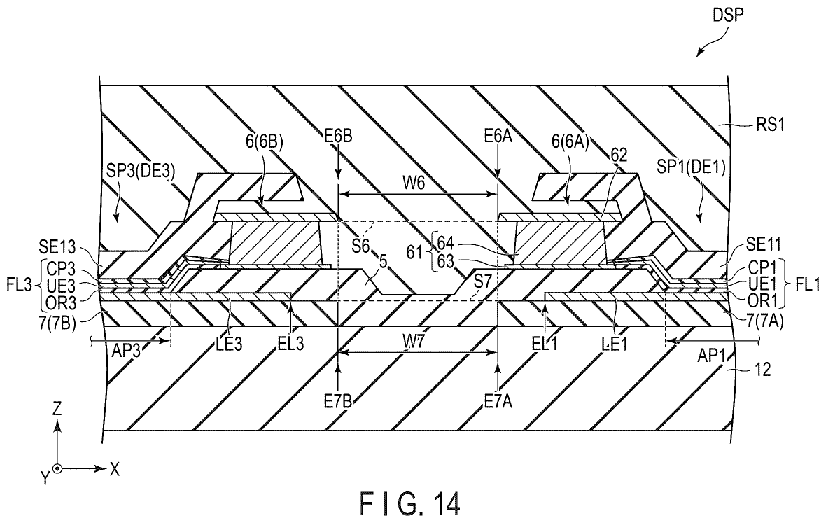

FIG. 14 is a cross-sectional view of another example of the display device DSP shown in FIG. 11. In the following example, the same or similar elements as those of the display device DSP in the example shown in FIG. 11 are referred to by the same reference numbers. Explanations of these same or similar elements are omitted.

In the example of FIG. 14, the end portion E7A and the end portion E6A align in plan view. Further, the end portion E7B and the end portion E6B align in plan view.

In the example of FIG. 14, the width W7 in the X-direction of the slit S7 is equivalent to the width W6 in the X-direction of the slit S6 (W7=W6). Thus, the slits S6 and S7 align in plan view. This configuration can achieve the same effect as the above-described effect.

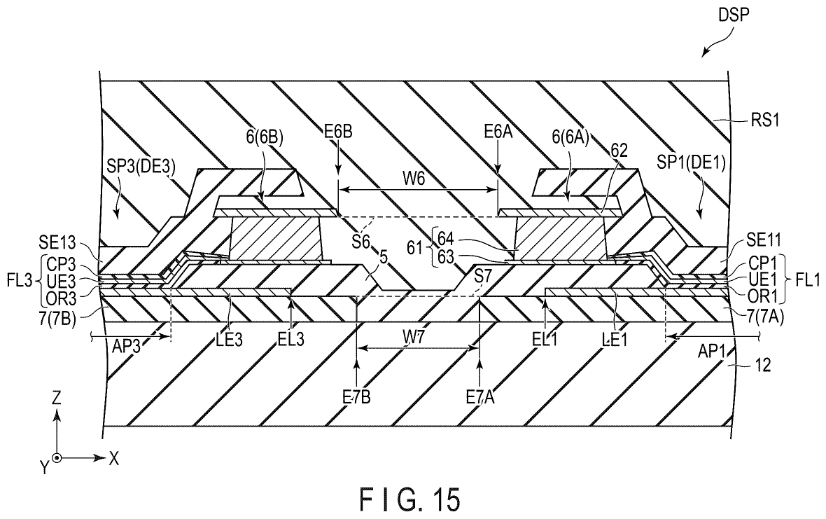

FIG. 15 is a cross-sectional view of still another example of the display device DSP shown in FIG. 11. In the example of FIG. 15, the end portion E7A protrudes relative to the end portion E6A. That is, the end portion E7A overlaps the slit S6 in plan view, but does not overlap the partition 6A in plan view. In the example of FIG. 15, the end portion E7B protrudes relative to the end portion E6B. That is, the end portion E7B overlaps the slit S6 in plan view, but does not overlap the partition 6B in plan view.

In the example of FIG. 15, the end portion E6A overlaps the inorganic insulating layer 7A in plan view, but does not overlap the slit S7 in plan view. Further, the end portion E6B overlaps the inorganic insulating layer 7B in plan view, but does not overlap the slit S7 in plan view.

In the example of FIG. 15, the width W7 in the X-direction of the slit S7 is smaller than the width W6 in the X-direction of the slit S6 (W7<W6). Thus, the partitions 6A and 6B do not overlap the slit S7 in plan view, but the inorganic insulating layers 7A and 7B overlap the slit S6 in plan view. This configuration can achieve the same effect as the above-described effect.

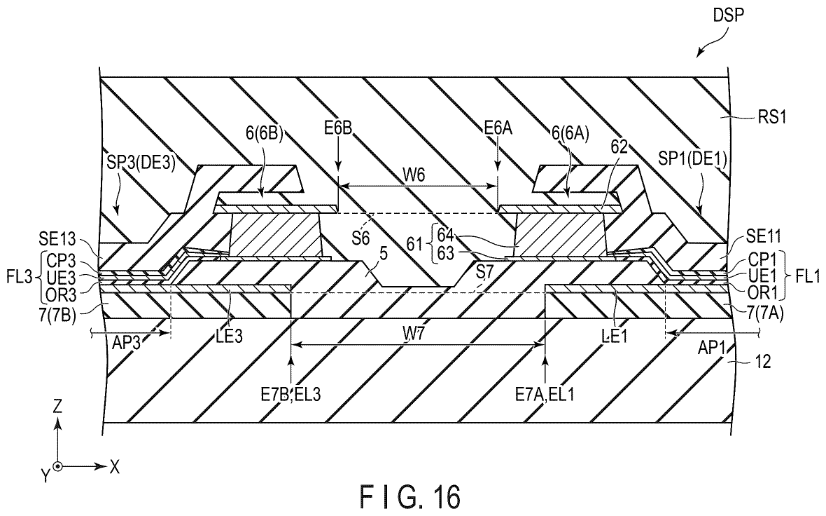

FIG. 16 is a cross-sectional view of still another example of the display device DSP shown in FIG. 11. In the example of FIG. 16, the end portion EL1 of the lower electrode LE1 and the end portion E7A of the inorganic insulating layer 7A align in plan view. Further, the end portion EL3 of the lower electrode LE3 and the end portion E7B of the inorganic insulating layer 7B align in plan view.

In the example of FIG. 16, the width W7 in the X-direction of the slit S7 is greater than the width W6 in the X-direction of the slit S6 (W7>W6). Thus, the partitions 6A and 6B overlap the slit S7 in plan view. The inorganic insulating layers 7A and 7B do not overlap the slit S6 in plan view. This configuration can achieve the same effect as the above-described effect.

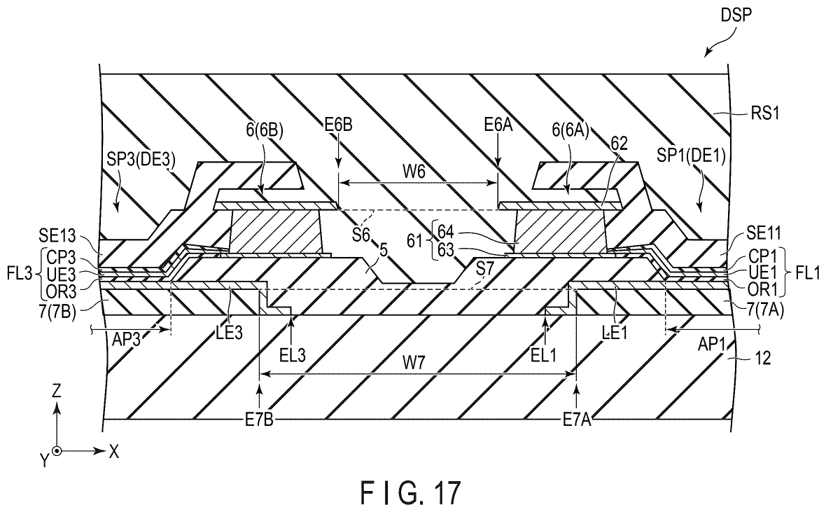

FIG. 17 is a cross-sectional view of still another example of the display device DSP shown in FIG. 11. In the example of FIG. 17, the end portion E7A of the inorganic insulating layer 7A is covered with the lower electrode LE1. Further, the end portion E7B of the inorganic insulating layer 7B is covered with the lower electrode LE3. Further, the lower electrodes EL1 and EL3 contact the organic insulating layer 12. This configuration can achieve the same effect as the above-described effect.

The positional relationships among the end portions E6A, E6B, E7A, E7B, EL1, and EL3 are not limited to the examples shown in FIG. 11 and FIG. 14 to FIG. 17. For example, the positional relationships may be the combinations of the positional relationships of the end portions in FIG. 11 and FIGS. 14 to 17. That is, the end portions E6A, E7A, and EL1 may not be respectively positioned symmetrically with the end portions E6B, E7B, and EL3 across an axis parallel to the Z-direction.

All of the display devices that can be implemented by a person of ordinary skill in the art through arbitrary design changes to the display device described above as the embodiment of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is:

1. A display device, comprising:
an organic insulating layer;
a first lower electrode provided above the organic insulating layer;
a second lower electrode provided above the organic insulating layer and spaced apart from the first lower electrode in a first direction;
an inorganic insulating layer provided between the organic insulating layer and the first lower electrode and the second lower electrode;
a rib layer having a first pixel aperture overlapping the first lower electrode and a second pixel aperture overlapping the second lower electrode; and
a partition having a lower portion provided on the rib layer and having conductivity and an upper portion provided on the lower portion and protruding relative to side surfaces of the lower portion, wherein the inorganic insulating layer has a first slit extending in a second direction intersecting the first direction,
the partition has a second slit extending in the second direction and overlapping the first slit in plan view, and
the first slit and the second slit are located between the first lower electrode and the second lower electrode.

2. The display device of claim 1, wherein
the first slit has a first width along the first direction,
the second slit has a second width along the first direction, and
the first width is greater than or equal to the second width.

3. The display device of claim 1, wherein
the rib layer contacts the organic insulating layer in the first slit.

4. The display device of claim 1, wherein
the inorganic insulating layer has a first end portion facing the first slit,
the partition has a second end portion facing the second slit, and
the first end portion is retracted relative to the second end portion.

5. The display device of claim 1, wherein
the inorganic insulating layer has a first end portion facing the first slit,
the partition has a second end portion facing the second slit, and
the first end portion and the second end portion align in plan view.

6. The display device of claim 1, wherein
the inorganic insulating layer has a first end portion facing the first slit,
the partition has a second end portion facing the second slit, and
the first end portion protrudes relative to the second end portion.

7. The display device of claim 4, wherein
the first end portion is covered with the rib layer.

8. The display device of claim 1, wherein
the first lower electrode has a third end portion, and
the third end portion does not overlap the second slit in plan view.

9. The display device of claim 4, wherein
the first lower electrode has a third end portion, and
the third end portion is retracted relative to the first end portion.

10. The display device of claim 4, wherein
the first lower electrode has a third end portion, and
the third end portion and the first end portion align in plan view.

11. The display device of claim 4, wherein
the first lower electrode covers the first end portion.

12. The display device of claim 1, wherein
the inorganic insulating layer overlaps the first pixel aperture and the second pixel aperture in plan view.

13. The display device of claim 1, wherein
the inorganic insulating layer has an aperture overlapping the rib layer in plan view.

14. The display device of claim 13, further comprising:
a pixel circuit provided below the organic insulating layer, wherein
the first lower electrode is connected to the pixel circuit through a contact hole provided in the organic insulating layer, and
the contact hole overlaps the aperture in plan view.

15. The display device of claim 13, wherein
the rib layer contacts the organic insulating layer in the aperture.

16. The display device of claim 1, further comprising:
a first organic layer covering the first lower electrode through the first pixel aperture;
a second organic layer covering the second lower electrode through the second pixel aperture;
a first upper electrode covering the first organic layer; and
a second upper electrode covering the second organic layer, wherein
the first organic layer and the second organic layer are configured to emit light in different colors, and
the first organic layer, the second organic layer, the first upper electrode, and the second upper electrode overlap the inorganic insulating layer in plan view.

17. The display device of claim 1, wherein
each of the first lower electrode and the second lower electrode has a layer formed of ITO.

18. The display device of claim 1, wherein
the inorganic insulating layer is formed of a material identical to that of the rib layer.

19. The display device of claim 1, wherein
the rib layer is formed of a silicon nitride or a silicon oxynitride.

20. The display device of claim 1, wherein
the inorganic insulating layer is formed of a silicon nitride or a silicon oxynitride.
